(19) United States
(12) Patent Application Publication
(10) Pub. No.: US 2018/0337680 A1
(43) Pub. Date: Nov. 22, 2018

(54) HIGH SPEED LEVEL SHIFTER FOR LOW VOLTAGE TO HIGH VOLTAGE CONVERSION

(71) Applicant: QUALCOMM Incorporated, San Diego, CA (US)

(72) Inventor: Subbarao Surendra Chakkirala, San Jose, CA (US)

(21) Appl. No.: 15/597,746

(22) Filed: May 17, 2017

(51) Int. Cl. H03K 19/003; H03K 19/21; H03K 19/0185; H03K 5/1534

(52) U.S. Cl. CPC H03K 19/00315; H03K 5/1534; H03K 19/018521; H03K 19/21

(57) ABSTRACT

Aspects of the disclosure are directed to a level shifter circuit. In accordance with one aspect, the level shifter circuit includes a high voltage device; a latch having a first side and a second side, wherein the latch is tied to a weak pull down to ground; and a pair of current-mirror transistors; wherein a first current-mirror transistor of the pair includes a first input coupled to the first side of the latch and a first output coupled to the high voltage device; and wherein a second current-mirror transistor of the pair includes a second input coupled to the second side of the latch and a second output coupled to the high voltage device.

### TECHNICAL FIELD

This disclosure relates generally to the field of level shifter, and, in particular, to a high speed level shifter for low voltage to high voltage conversion.

### BACKGROUND

Level shifters are used in digital electronics to change voltage levels from one state to another. Conventional level shifters which transform a low voltage level to a high voltage level may include several design challenges. Conventional level shifters may require protection devices to ensure reliability as gate oxides of various transistors within the level shifter circuit may be vulnerable to damage from higher voltages. The increased complexity of protection devices within the level shifter circuit may lead to an undesirable increase in form factor (i.e. circuit area). Moreover, the additional circuitry generally leads to increased signal propagation delay which ultimately limits the maximum operational speed of the digital electronics. The increased propagation delay may result in greater dispersion in the timing tolerance for signal rise and fall times. This characteristic may limit its usage as some applications may have sensitivity to signal waveform asymmetry. Hence, a more efficient, higher performing level shifter circuit with one or more of the following characteristics of a smaller form factor, lower delay, higher switching speed, increased reliability, and/or improved waveform symmetry is desired.

### SUMMARY

The following presents a simplified summary of one or more aspects of the present disclosure, in order to provide a basic understanding of such aspects. This summary is not an extensive overview of all contemplated features of the disclosure, and is intended neither to identify key or critical elements of all aspects of the disclosure nor to delineate the scope of any or all aspects of the disclosure. Its sole purpose is to present some concepts of one or more aspects of the disclosure in a simplified form as a prelude to the more detailed description that is presented later.

In one aspect, the disclosure provides a level shifter circuit including a high voltage device; a latch having a first side and a second side, wherein the latch is tied to a weak pull down to ground; and a pair of current-mirror transistors; wherein a first current-mirror transistor of the pair includes a first current-mirror input coupled to the first side of the latch and a first current-mirror output coupled to the high voltage device; and wherein a second current-mirror transistor of the pair includes a second current-mirror input coupled to the second side of the latch and a second current-mirror output coupled to the high voltage device. In one example, the latch includes a pair of diode-connected transistors, the pair of diode-connected transistors coupled to the weak pull down to ground through their gates. In one example, the high voltage device includes a pair of inverters. In one example, the weak pull down to ground is implemented by a pair of complementary input transistors. The level shifter circuit may also include a high voltage source coupled to the pair of current-mirror transistors. In one aspect, the level shifter circuit also includes a pulse edge detector, wherein the pulse edge detector outputs a pulse waveform to a first input of the level shifter circuit and outputs a complementary pulse waveform to a second input of the level shifter circuit, the complementary pulse waveform being a complement of the pulse waveform. The pulse waveform represents a plurality of leading edges of the square wave, and the complementary pulse waveform represents a plurality of falling edges of the square wave. The pulse edge detector may include at least two inverters, an XOR gate and a pair of AND gates, wherein the at least two inverters, the XOR gate and the pair of AND gates are coupled to each other in series. The pulse edge detector may further include a delay element, the delay element coupled in series between the at least two inverters and the XOR gate. In one example, a square wave is inputted to one of the at least two inverters and to a first AND gate of the pair of AND gates; and wherein an inverted square wave is inputted to the second AND gate of the pair of AND gates, the inverted square wave being a complement of the square wave.

Another aspect of the disclosure provides a level shifter circuit, including a ground and a high voltage source; a first inverter having a first inverter input and a first inverter output; a second inverter having a second inverter input and a second inverter output; a pair of complementary input transistors having a first input transistor and a second input transistor, wherein the first input transistor includes a first input gate, a first input drain, and a first input source coupled to the ground, and the second input transistor includes a second input gate, a second input drain, and a second input source coupled to the ground; a first diode-connected transistor having a first diode-connected source, a first diode-connected drain and a first diode-connected gate, wherein the first diode-connected drain and the first diode-connected gate are coupled to the first input drain; a second diode-connected transistor having a second diode-connected source, a second diode-connected drain and a second diode-connected gate, wherein the second diode-connected drain and the second diode-connected gate are coupled to the second input drain; and a pair of complementary current-mirror transistors having a first current-mirror transistor and a second current-mirror transistor; wherein the first current-mirror transistor includes a first current-mirror gate coupled to the first diode-connected gate, a first current-mirror drain coupled to the first inverter input and the second inverter output, and a first current-mirror source coupled to the high voltage source; and wherein the second current-mirror transistor includes a second current-mirror gate coupled to the second diode-connected gate, a second current-mirror drain coupled to the first inverter output and the second inverter input, and a second current-mirror source coupled to the high voltage source.

In one example, the second inverter output is a first output of the level shifter circuit, and the first inverter output is a second output of the level shifter circuit. In one example, the first input gate is a first level shifter input, and the second input gate is a second level shifter input. In one example, a pulse waveform is inputted to the level shifter circuit through the first level shifter input, and a complementary pulse waveform is inputted through the second level shifter input, the complementary pulse waveform being a complement of the pulse waveform.

The level shifter circuit may further include a pulse edge detector; wherein the pulse edge detector outputs the pulse waveform to the first level shifter input and the complementary pulse waveform to the second level shifter input. The pulse edge detector may include at least two inverters, an XOR gate and a pair of AND gates, wherein the at least two inverters, the XOR gate and the pair of AND gates are coupled to each other in series. For example, the pulse edge detector may include a third inverter coupled in series to a fourth inverter; an XOR gate coupled in series to the fourth inverter; and a pair of AND gates coupled in parallel to each other, wherein the pair of AND gates is coupled in series to the XOR gate. A square wave is inputted to the third inverter and to a first AND gate of the pair of AND gates; and wherein an inverted square wave is inputted to the second AND gate of the pair of AND gates, the inverted square wave being a complement of the square wave. The first AND gate outputs a pulse waveform, the second AND gate outputs a complementary pulse waveform, the complementary pulse waveform being a complement of the pulse waveform. The pulse waveform is inputted to the level shifter circuit through the first input gate and the complementary pulse waveform is inputted through the second input gate.

Another aspect of the disclosure provides a method for placement and routing one or more components on a level shifter circuit, the method including placing a high voltage device on the level shifter circuit; placing a weak pull down to ground on the level shifter circuit; coupling a latch to the weak pull down to ground, wherein the latch has a first side and a second side; coupling a first input of a first current-mirror transistor to the first side of the latch, and coupling a first output of the first current-mirror transistor to the high voltage device; and coupling a second input of a second current-mirror transistor to the second side of the latch, and coupling a second output of the second current-mirror transistor to the high voltage device. The method may further include coupling a high voltage source to the first current-mirror transistor and to the second current-mirror transistor. In one example, the coupling the latch to the weak pull down to ground includes coupling a pair of diode-connected transistors to the weak pull down to ground through their gates. In one example, the high voltage device includes a first inverter and a second inverter, and wherein a first inverter output is coupled to a second inverter input, and a second inverter output is coupled to a first inverter input.

In one example, the method further includes coupling a third inverter in series to a fourth inverter; coupling a delay element in series to the fourth inverter; coupling an XOR gate in series to the delay element; and coupling a pair of AND gates in series to the XOR gate, wherein the pair of AND gates are coupled in parallel to each other. The method may also include placing a first input transistor on the level shifter circuit and implementing the weak pull down to ground by coupling a first input source to a ground and by coupling a first input drain to a first diode-connected gate of the latch; and placing a second input transistor on the level shifter circuit and implementing the weak pull down to ground by coupling a second input source to the ground and by coupling a second input drain to a second diode-connected gate of the latch.

Another aspect of the disclosure provides a level shifter circuit including means for supplying a high voltage to the level shifter circuit; means for grounding the level shifter circuit; means for inputting at least one pulse waveform into the level shifter circuit, wherein the means for inputting the at least one pulse waveform is coupled to the means for grounding; means for shunting an input current from the means for inputting; means for generating a mirrored current associated with the means for inputting; and means for latching an input voltage associated with the input current. In one example, the means for supplying the high voltage is a DC power supply, and the means for grounding is a conductor to a common voltage. In one example, the means for inputting may include at least two transistors. In one example, the means for shunting may include at least two diode-connected transistors. The diode-connected transistors may be metal oxide semiconductor (MOS) transistors. In one example, the means for generating the mirrored current may include at least two transistors. The transistors may be metal oxide semiconductor (MOS) transistors. The gates of the respective transistors are coupled to the gates of the two respective diode-connected transistors. In one example, the means for latching may include at least two inverters configured in a feedback loop to each other.

In one aspect, the level shifter circuit may further include means for generating the at least one pulse waveform. The means for generating the at least one pulse waveform may include a first inverter in series to a second inverter; a delay element in series to the second inverter; an XOR gate in series to the delay element; and a pair of AND gates in series to the XOR gate, wherein the pair of AND gates are coupled in parallel to each other.

These and other aspects of the invention will become more fully understood upon a review of the detailed description, which follows. Other aspects, features, and embodiments of the present invention will become apparent to those of ordinary skill in the art, upon reviewing the following description of specific, exemplary embodiments of the present invention in conjunction with the accompanying figures. While features of the present invention may be discussed relative to certain embodiments and figures below, all embodiments of the present invention can include one or more of the advantageous features discussed herein. In other words, while one or more embodiments may be discussed as having certain advantageous features, one or more of such features may also be used in accordance with the various embodiments of the invention discussed herein. In similar fashion, while exemplary embodiments may be discussed below as device, system, or method embodiments it should be understood that such exemplary embodiments can be implemented in various devices, systems, and methods.

### BRIEF DESCRIPTION OF THE DRAWINGS

FIG. 1 illustrates an example circuit diagram of a conventional level shifter circuit.

FIG. 2 illustrates an example pulse edge detector circuit for a level shifter in accordance with the present disclosure.

FIG. 3 illustrates an example square wave input waveform and its two corresponding pulse waveforms.

FIG. 4 illustrates an example level shifter circuit in accordance with the present disclosure.

FIG. 5 illustrates an example flow diagram for placement and routing of one or more components on a level shifter circuit.

### DETAILED DESCRIPTION

The detailed description set forth below in connection with the appended drawings is intended as a description of various configurations and is not intended to represent the only configurations in which the concepts described herein may be practiced. The detailed description includes specific details for the purpose of providing a thorough understanding of various concepts. However, it will be apparent to those skilled in the art that these concepts may be practiced without these specific details. In some instances, well known structures and components are shown in block diagram form in order to avoid obscuring such concepts.

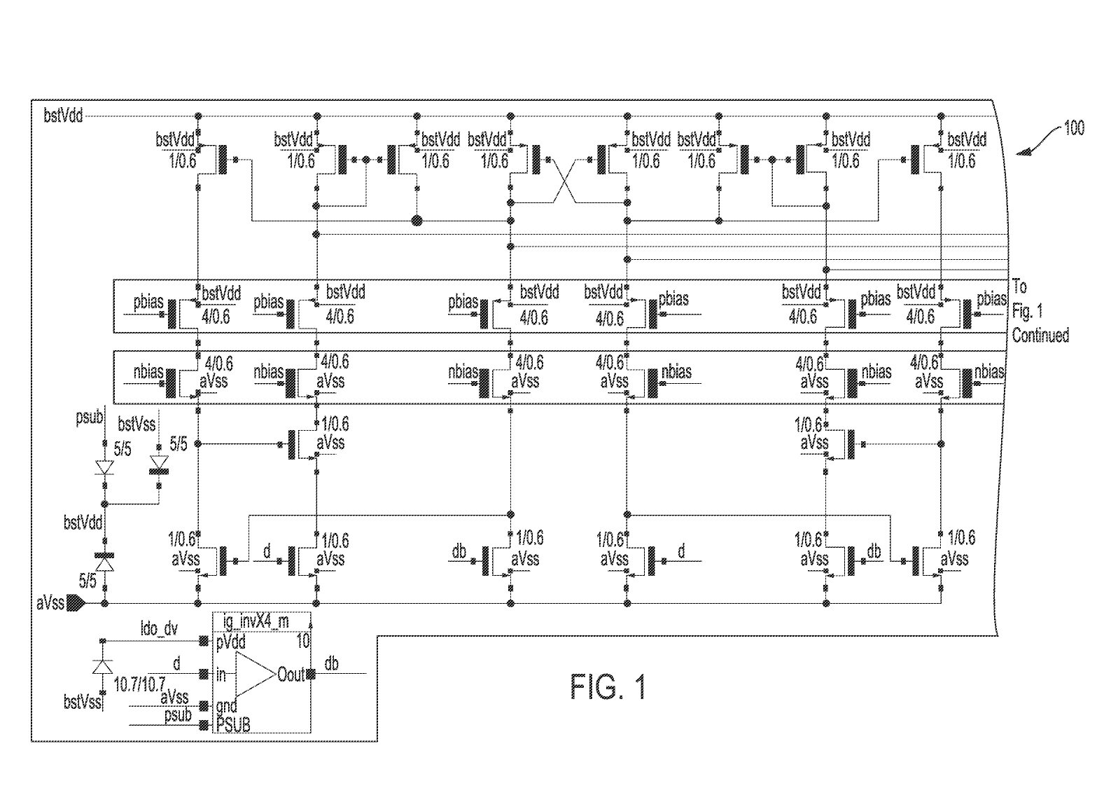

FIG. 1 illustrates an example circuit diagram of a conventional level shifter circuit 100. In the conventional level shifter circuit 100, high voltage (e.g. 12 v) transistors are placed along the middle of the circuit diagram and low voltage (e.g. 5 v) transistors are placed along the top and bottom of the circuit diagram. In the conventional level shifter circuit 100, there are possible leakage paths from the high voltage transistors to the low voltage transistors. Leakage paths can cause performance degradation and possible damage in the low voltage transistors.

Differing from the conventional level shifter, various aspects of the present disclosure relate to systems and methods for level shifter circuits that may be more efficient and have higher performance than conventional level shifters. Characteristics of the level shifters of the present disclosure may include one or more of: smaller form factor, shorter propagation delay, faster operational speed, increased reliability and/or improved waveform symmetry than conventional level shifters.

In digital electronic circuits, level shifters may be used to modify a signal voltage level from one state to a different state. For example, level shifters may be used to transform digital logic levels from one voltage level to another voltage level due to different digital electronic circuit logic families

Protection circuitry in a level shifter may ensure circuit reliability and integrity. However, protection circuitry increases form factor, for example, increased circuit area. The present disclosure includes designs for level shifter circuits that balance the requirement of protection circuitry with ensuring circuit reliability and integrity. Since too much protection circuitry generally leads to increased propagation delay (i.e., increased signal propagation delay) which may limit the maximum operational speed of the level shifter, appropriate placements of the protection circuitry to reduce its quantity will minimize propagation delay and maximize operational speed. By introducing optimized placements of the protection circuitry to minimize its quantity in a level shifter, many undesired characteristics are reduced or mitigated, for example, dispersion in the timing tolerance for signal rise and fall times, i.e., increased signal waveform asymmetry, and limiting the usage of the level shifter as some circuit applications may have greater sensitivity to signal waveform asymmetry.

In one aspect, the present disclosure discloses level shifter circuits that provide inherent protection of its circuitry by restricting the voltage range at various points in the circuit. In addition, the level shifter circuits yield a smaller form factor, a shorter propagation delay and a symmetric rise/fall time characteristic. The shorter propagation delay results in a higher operational frequency, for example, up to approximately 250 MHz.

Transistors which are part of the components of the level shifter circuit may be based on LDMOS (laterally diffused metal oxide semiconductor) technology, DEMOS (drain extended metal oxide semiconductor) technology, etc. The various placements and electrical coupling of the transistors with respect to each other and with respect to other components in the level shifter are designed so that the vulnerability to damage from high voltage levels to the gate oxides of various transistors within the level shifter are minimized.

The present disclosure allows for a level shifter circuit with a smaller form factor, shorter propagation delay, faster operational speed, increased reliability and/or improved waveform symmetry. The present disclosure includes a level shifter which generates a complementary pair of high voltage waveforms with a period T. In one aspect, the improved level shifter accepts a leading-edge detector input pulse and a falling-edge detector input pulse from a low voltage waveform with the period T. In one example, the low voltage waveform has a voltage amplitude level of 5 volts and the complementary pair of high voltage waveforms have voltage amplitudes of +12 volts and −12 volts, respectively. The maximum high voltage DC bias is at 12 volts and the maximum low voltage DC bias is at 5 volts.

The high voltage waveforms may be generated using a pair of high voltage transistors which drive a pair of low voltage digital inverters through a set of diode-connected transistors and a set of current mirror transistors to produce the complementary pair of high voltage waveforms. The high voltage transistors are rated to sustain a biasing voltage up to a maximum high voltage dc bias. The low voltage digital inverters are rated to sustain a biasing voltage up to the maximum low voltage dc bias without the use of additional protection circuitry. Also, the diode-connected transistors are rated to sustain a biasing voltage up to the maximum low voltage DC bias without the use of additional protection circuitry. In one aspect, the pair of high voltage transistors alternately turn on and off based on a trigger from the leading-edge detector input pulse and from the falling-edge detector input pulse.

The leading-edge detector input pulse and the falling-edge detector input pulse may be generated by an edge detection circuit which synthesizes the input pulses using logical circuitry which employs an exclusive OR combination of the low voltage waveform and a delayed version of the low voltage waveform. In one example, the exclusive OR combination is a logical operation with two inputs which produces a logical HIGH output if one and only one input is asserted HIGH and produces a logical LOW output if both inputs are either asserted LOW or asserted HIGH.

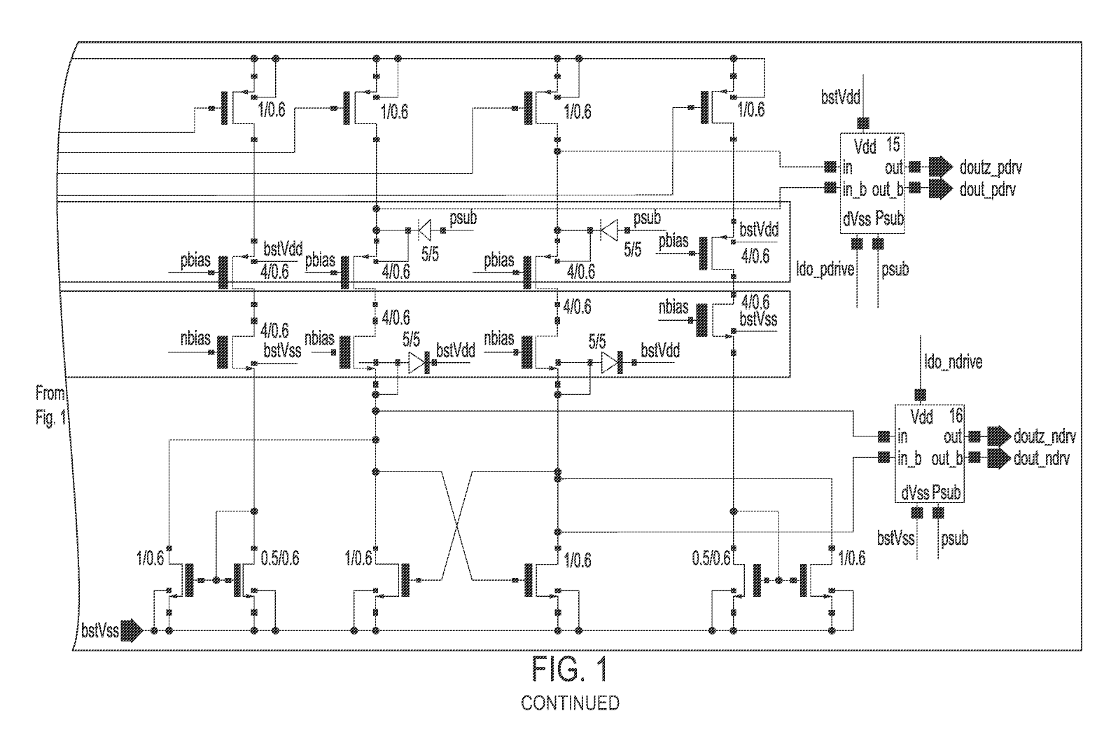

FIG. 2 illustrates an example pulse edge detector circuit 200 for a level shifter. In one example, a square wave input waveform Din 210 is sent to a first inverter 220 and to a first input of an XOR gate 250. The first inverter 220 produces an inverted square wave input waveform Din_b 225 which is a logical complement of the square wave input waveform Din 210. The inverted square wave input waveform Din_b 225 is fed to a second inverter 230 and a delay element 240 to produce a delayed waveform 245 as a second input of the XOR gate 250. The output 255 of the XOR gate 250 is sent to a first input of a first AND gate 260 and a first input of a second AND gate 270. The square wave input waveform Din 210 is sent to a second input of the first AND gate 260 to produce a first pulse waveform (e.g., leading-edge pulse waveform Din_pulse 280). The inverted square wave input waveform Din_b 225 is sent to a second input of the second AND gate 270 to produce a second pulse waveform (e.g., falling-edge pulse waveform Din_b_pulse 290). In one aspect, the pulse edge detector circuit 200 outputs a first pulse waveform (leading-edge pulse waveform Din_pulse 280) and a second pulse waveform (falling-edge pulse waveform Din_b_pulse 290).

In one example, the leading-edge pulse waveform Din_pulse 280 is synchronous with a leading-edge of the square wave input waveform Din 210, and the falling-edge pulse waveform Din_b_pulse 290 is synchronous with a falling edge of the square wave input waveform Din 210. That is, the leading-edge pulse waveform Din_pulse 280 includes a plurality of pulses that represent the leading edges of the square wave input waveform Din 210, and the falling-edge pulse waveform Din_b_pulse 290 includes a plurality of pulses that represent the falling edges of the square wave input waveform Din 210.

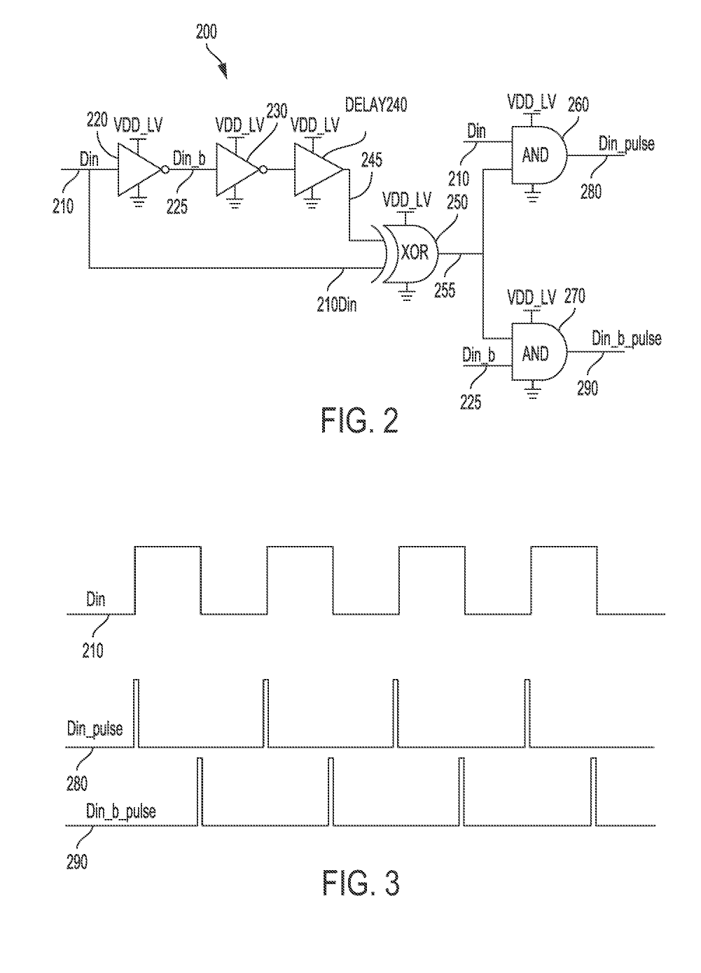

FIG. 3 illustrates an example square wave input waveform (Din 210) and its two corresponding pulse waveforms (i.e., a leading-edge pulse waveform Din_pulse 280 and a falling-edge pulse waveform Din_b_pulse 290). The square wave input waveform Din 210 serves as the input to the pulse edge detector circuit 200 (shown in FIG. 2). In one example, the square wave input waveform Din 210 has a duty factor of 50%. In another example, the square wave input waveform Din 210 has a duty factor of less than 50%. In yet another example, the square wave input waveform Din 210 has a duty factor of greater than 50%.

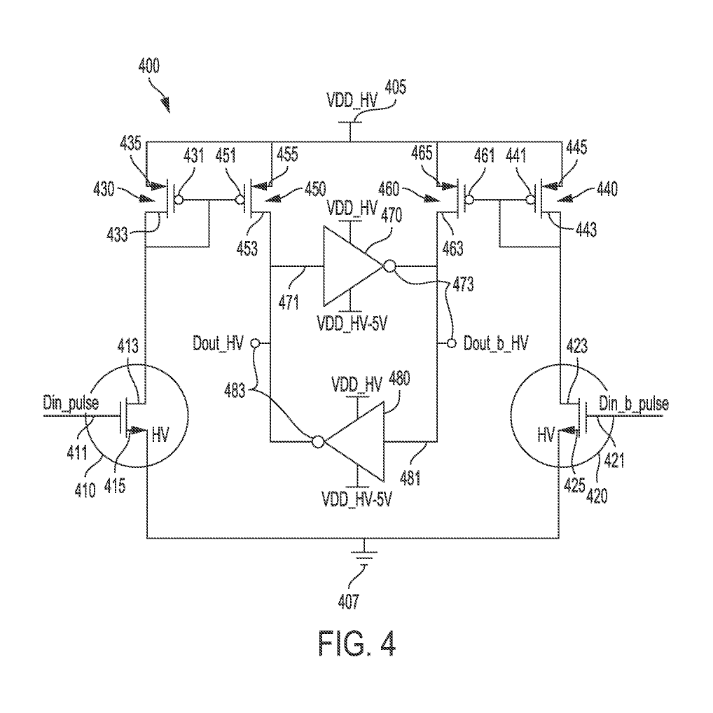

FIG. 4 illustrates an example level shifter circuit 400 in accordance with the present disclosure. In one example, the level shifter circuit 400 includes a high voltage device and a latch having a first side and a second side. The latch is, for example, tied to a weak pull down to ground and a pair of current-mirror transistors. The pair of current-mirror transistors may be coupled to a high voltage source. A first current-mirror transistor of the pair of current-mirror transistors may include a first current-mirror input which is coupled to the first side of the latch and may include a first current-mirror output which is coupled to the high voltage device. In one example, the first current-mirror input of the first current-mirror transistor is a first current-mirror gate 451, and the first current-mirror output of the first current-mirror transistor is a first current-mirror source 455. And, a second current-mirror transistor of the pair of current-mirror transistors may include a second current-mirror input which is coupled to the second side of the latch and may include a second current-mirror output which is coupled to the high voltage device. In one example, the second current-mirror input of the second current-mirror transistor is a second current-mirror gate 461, and the second current-mirror output of the second current-mirror transistor is a second current-mirror source 465.

In one example, the latch includes a pair of diode-connected transistors and the pair of diode-connected transistors are coupled to the weak pull down to ground through their gates. The weak pull down to ground may be implemented by a pair of complementary input transistors. In one example, the high voltage device includes a pair of inverters.

In one aspect, the level shifter circuit 400 includes a pulse edge detector, for example, the pulse edge detector 200 shown in FIG. 2. In one example, the pulse edge detector may include at least two inverters, an XOR gate and a pair of AND gates. The at least two inverters, the XOR gate and the pair of AND gates may be coupled to each other in series. In one example, the pulse edge detector may also include a delay element. The delay element may be coupled in series between the at least two inverters and the XOR gate.

For example, a square wave (e.g., square wave input waveform Din 210) is inputted to one of the at least two inverters of the pulse edge detector and also inputted to a first AND gate of the pair of AND gates. An inverted square wave (e.g., inverted square wave input waveform Din_b 225) is inputted to the second AND gate of the pair of AND gates. The inverted square wave (e.g., inverted square wave input waveform Din_b 225) is a complement of the square wave (e.g., square wave input waveform Din 210).

For example, the pulse edge detector may output a pulse waveform (e.g., leading-edge pulse waveform Din_pulse 280) to a first current-mirror input of the level shifter circuit 400 and outputs a complementary pulse waveform (e.g., falling-edge pulse waveform Din_b_pulse 290) to a second input of the level shifter circuit. The complementary pulse waveform is a complement of the pulse waveform. The pulse waveform (e.g., leading-edge pulse waveform Din_pulse 280) represents a plurality of leading edges of the square wave (e.g., square wave input waveform Din 210), and the complementary pulse waveform (e.g., falling-edge pulse waveform Din_b_pulse 290) represents a plurality of falling edges of the square wave (e.g., square wave input waveform Din 210).

In one example, the level shifter circuit 400 includes a high voltage source 405 and a ground 407. The level shifter circuit 400 may also include a first inverter 470 having a first inverter input 471 and a first inverter output 473, and a second inverter 480 having a second inverter input 481 and a second inverter output 483. Also included is a pair of complementary input transistors (i.e., a first input transistor 410 and a second input transistor 420). The first input transistor 410 includes a first input gate 411, a first input drain 413, and a first input source 415 coupled to the ground 407. The second input transistor 420 includes a second input gate 421, a second input drain 423, and a second input source 425 coupled to the ground 407. The level shifter circuit 400 may also include a first diode-connected transistor 430 having a first diode-connected source 435, a first diode-connected drain 433 and a first diode-connected gate 431, wherein the first diode-connected drain 433 and the first diode-connected gate 431 are coupled to the first input drain 413. The level shifter circuit 400 may further include a second diode-connected transistor 440 having a second diode-connected source 445, a second diode-connected drain 443 and a second diode-connected gate 441, wherein the second diode-connected drain 443 and the second diode-connected gate 441 are coupled to the second input drain 423. In one example, the first diode-connected transistor 430 and the second diode-connected transistor 440 operate with a low supply voltage, for example, 5 volts. One skilled in the art would understand that other voltage values for the low supply voltage may be used for a particular application and are within the scope and spirit of the present disclosure.

In one example, the level shifter circuit 400 includes a pair of complementary current-mirror transistors (i.e., a first current-mirror transistor 450 and a second current-mirror transistor 460). The first current-mirror transistor 450 includes a first current-mirror gate 451 coupled to the first diode-connected gate 431, a first current-mirror drain 453 coupled to the first inverter input 471 and the second inverter output 483, and a first current-mirror source 455 coupled to the high voltage source 405. The second current-mirror transistor 460 includes a second current-mirror gate 461 coupled to the second diode-connected gate 441, a second current-mirror drain 463 coupled to the first inverter output 473 and the second inverter input 481, and a second current-mirror source 465 coupled to the high voltage source 405.

In one example, the second inverter output 483 is a first output of the level shifter circuit, and the first inverter output 473 is a second output of the level shifter circuit. In one example, the first input gate 411 is a first level shifter input, and the second input gate 421 is a second level shifter input.

In one example, the level shifter circuit 400 includes a pulse edge detector (e.g., the pulse edge detector 200 shown in FIG. 2). The pulse edge detector 200 may include two inverters 220, 230 coupled to each other in series, an XOR gate 250 coupled in series to one of the two inverters, and a pair of AND gates 260, 270 coupled in parallel to each other with the pair of AND gates coupled in series to the XOR gate.

For example, a square wave (e.g., square wave input waveform Din 210) is inputted to one of the two inverters of the pulse edge detector and also inputted to a first AND gate 260 of the pair of AND gates. An inverted square wave (e.g., inverted square wave input waveform Din_b 225) is inputted to the second AND gate 270 of the pair of AND gates. The inverted square wave (e.g., inverted square wave input waveform Din_b 225) is a complement of the square wave (e.g., square wave input waveform Din 210).

For example, the pulse edge detector may output a pulse waveform (e.g., leading-edge pulse waveform Din_pulse 280) which is inputted to the first level shifter input (i.e., first input gate 411). The pulse edge detector may also output a complementary pulse waveform (e.g., falling-edge pulse waveform Din_b_pulse 290) which is inputted to the second level shifter input (i.e., second input gate 421). That is, the first AND gate 260 outputs a pulse waveform, and the second AND gate 270 outputs a complementary pulse waveform. The complementary pulse waveform is a complement of the pulse waveform. The pulse waveform (e.g., leading-edge pulse waveform Din_pulse 280) represents a plurality of leading edges of the square wave (e.g., square wave input waveform Din 210), and the complementary pulse waveform (e.g., falling edge pulse waveform Din_b_pulse 290) represents a plurality of falling edges of the square wave (e.g., square wave input waveform Din 210).

In one example, as the first pulse waveform (e.g., leading-edge pulse waveform Din_pulse 280) transitions to a HIGH state, the first input transistor 410 conducts current between its first input source 415 and first input gate 411. When the first input transistor 410 conducts current between its first input source 415 and its first input gate 411, the first diode-connected gate 431 of the first diode-connected transistor 430 is pulled to a LOW state. In another example, as the second pulse waveform (e.g., falling-edge pulse waveform Din_b_pulse 290) remains at a LOW state, the second input transistor 420 does not conduct current between its second input source 425 and its second input gate 421. When the second input transistor 420 does not conduct current between its second input source 425 and its second input gate 421, the second diode-connected gate 441 of the second diode-connected transistor 440 is pulled to a HIGH state. Each of the first pulse waveform and the second pulse waveform has two voltage states: a LOW state and a HIGH state. A LOW state is at a lower voltage than a HIGH state. Conversely, a HIGH state is at a higher voltage than a LOW state.

In one example, the first inverter output 473 (labeled as Dout_b_HV in FIG. 4) transitions to a WIDER LOW state, and the second inverter output 483 (labeled as Dout_HV in FIG. 4) transitions to a WIDER HIGH state. The WIDER LOW state is at a lower voltage than the LOW state, and the WIDER HIGH state is at a higher voltage than the HIGH state.

As shown in FIG. 4, the first inverter 470 and second inverter 480 are connected in a positive feedback configuration. For example, positive feedback may have benefits such as a faster response time and maintenance of its circuit output voltage when its circuit input voltage changes. In one example, the second inverter 480 is a negative metal oxide semiconductor (NMOS) transistor and the first inverter 470 is a positive metal oxide semiconductor (PMOS) transistor. As an example, the first inverter 470 has an output range of VDD_HV to VDD_HV −5V, and the second inverter 480 also has an output range of VDD_HV to VDD_HV −5V, where VDD_HV is the voltage of the high voltage source 405.

In one example, as the second pulse waveform (e.g., falling-edge pulse waveform Din_b_pulse 290) transitions to a HIGH state, the second input transistor 420 conducts current between its source and gate terminals. When the second input transistor 420 conducts current between its second input source 425 and its second input gate 421, the second diode-connected gate 441 of the second diode-connected transistor 440 is pulled to a LOW state. In another example, as the first pulse waveform (e.g., leading-edge pulse waveform Din_pulse 280) remains at a LOW state, the first input transistor 410 does not conduct current between its first input source 415 and its first input gate 411.

When the first input transistor 410 does not conduct current between its first input source 415 and its first input gate 411, the first diode-connected gate 431 of the first diode-connected transistor 430 is pulled to a HIGH state. In one example, the first inverter output 473 (labeled as Dout_b_HV in FIG. 4) transitions to a WIDER HIGH state, and the second inverter output 483 (labeled as Dout_HV in FIG. 4) transitions to a WIDER LOW state.

In another example, after the first pulse waveform (e.g., leading-edge pulse waveform Din_pulse 280) transitions from the HIGH state to a LOW state, the first input transistor 410 does not conduct current between its first input source 415 and its first input gate 411. However, the first inverter 470 and the second inverter 480 hold their state. For example, the first inverter output 473 (labeled as Dout_b_HV in FIG. 4) remains at the WIDER LOW state, and the second inverter output 483 (labeled as Dout_HV in FIG. 4) transitions to a WIDER HIGH state.

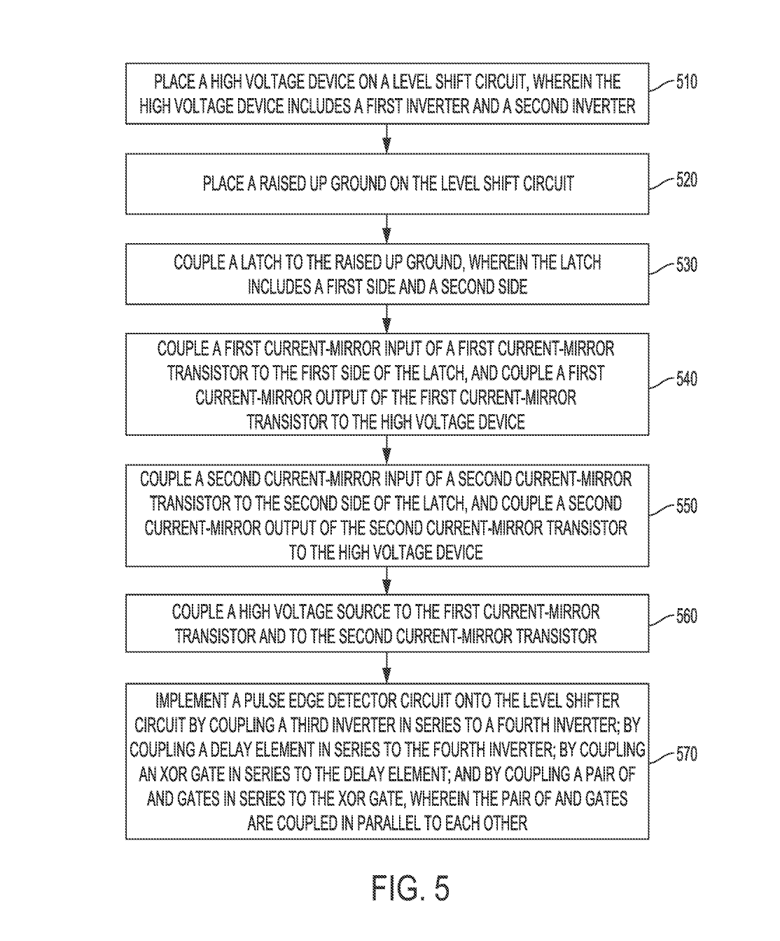

FIG. 5 illustrates an example flow diagram 500 for placement and routing of one or more components on a level shifter circuit. In block 510, place a high voltage device on the level shifter circuit. In one example, the high voltage device includes a first inverter and a second inverter. And, a first inverter output of the first inverter is coupled to a second inverter input of the second inverter, and a second inverter output of the second inverter is coupled to a first inverter input of the first inverter.

In block 520, place a weak pull down to ground on the level shifter circuit. In one example, further place a first input transistor on the level shifter circuit and implement the weak pull down to ground by coupling a first input source to a ground and by coupling a first input drain to a first diode-connected gate of the latch; and place a second input transistor on the level shifter circuit and implement the weak pull down to ground by coupling a second input source to the ground and by coupling a second input drain to a second diode-connected gate of the latch.

In block 530, couple a latch to the weak pull down to ground. In one example, the latch includes a first side and a second side. In one example, the first side includes a diode-connected transistor and the second side includes another diode-connected transistor. In one example, coupling the latch to the weak pull down to ground is implemented by coupling a pair of diode-connected transistors to the weak pull down to ground through their gates. That is, a first diode-connected gate of a first diode-connected transistor is coupled to a first input drain of a first input transistor and a first input source of the first input transistor is coupled to a ground. And, a second diode-connected gate of a second diode-connected transistor is coupled to a second input drain of a second input transistor and a second input source of the second input transistor is coupled to the ground.

In block 540, couple a first current-mirror input of a first current-mirror transistor to the first side of the latch, and couple a first current-mirror output of the first current-mirror transistor to the high voltage device. In one example, the first current-mirror input of the first current-mirror transistor is a first current-mirror gate, and the first current-mirror output of the first current-mirror transistor is a first current-mirror drain.

In block 550, couple a second current-mirror input of a second current-mirror transistor to the second side of the latch, and couple a second current-mirror output of the second current-mirror transistor to the high voltage device. In one example, the second current-mirror input of the second current-mirror transistor is a second current-mirror gate, and the second current-mirror output of the second current-mirror transistor is a second current-mirror drain. In block 560, couple a high voltage source to the first current-mirror transistor and to the second current-mirror transistor.

In block 570, implement a pulse edge detector circuit onto the level shifter circuit by coupling a third inverter in series to a fourth inverter; by coupling a delay element in series to the fourth inverter; by coupling an XOR gate in series to the delay element; and by coupling a pair of AND gates in series to the XOR gate, wherein the pair of AND gates are coupled in parallel to each other.

In one example, one or more processors may be used to execute software or firmware needed to perform the steps in the flow diagram of FIG. 5. Software shall be construed broadly to mean instructions, instruction sets, code, code segments, program code, programs, subprograms, software modules, applications, software applications, software packages, routines, subroutines, objects, executables, threads of execution, procedures, functions, etc., whether referred to as software, firmware, middleware, microcode, hardware description language, or otherwise. The software may reside on a computer-readable medium. The computer-readable medium may be a non-transitory computer-readable medium. A non-transitory computer-readable medium includes, by way of example, a magnetic storage device (e.g., hard disk, floppy disk, magnetic strip), an optical disk (e.g., a compact disc (CD) or a digital versatile disc (DVD)), a smart card, a flash memory device (e.g., a card, a stick, or a key drive), a random access memory (RAM), a read only memory (ROM), a programmable ROM (PROM), an erasable PROM (EPROM), an electrically erasable PROM (EEPROM), a register, a removable disk, and any other suitable medium for storing software and/or instructions that may be accessed and read by a computer. The computer-readable medium may also include, by way of example, a carrier wave, a transmission line, and any other suitable medium for transmitting software and/or instructions that may be accessed and read by a computer. The computer-readable medium may reside in the processing system 301, external to the processing system, or distributed across multiple entities including the processing system. The computer-readable medium may be embodied in a computer program product. By way of example, a computer program product may include a computer-readable medium in packaging materials. The computer-readable medium may include software or firmware for placement and routing of one or more components on a level shifter circuit. Those skilled in the art will recognize how best to implement the described functionality presented throughout this disclosure depending on the particular application and the overall design constraints imposed on the overall system.

Any circuitry included in the processor(s) is merely provided as an example, and other means for carrying out the described functions may be included within various aspects of the present disclosure, including but not limited to the instructions stored in the computer-readable medium, or any other suitable apparatus or means described herein, and utilizing, for example, the processes and/or algorithms described herein in relation to the example flow diagram.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling between two objects. For example, if object A physically touches object B, and object B touches object C, then objects A and C may still be considered coupled to one another—even if they do not directly physically touch each other. For instance, a first die may be coupled to a second die in a package even though the first die is never directly physically in contact with the second die. The terms “circuit” and “circuitry” are used broadly, and intended to include both hardware implementations of electrical devices and conductors that, when connected and configured, enable the performance of the functions described in the present disclosure, without limitation as to the type of electronic circuits, as well as software implementations of information and instructions that, when executed by a processor, enable the performance of the functions described in the present disclosure.

One or more of the components, steps, features and/or functions illustrated in the figures may be rearranged and/or combined into a single component, step, feature or function or embodied in several components, steps, or functions. Additional elements, components, steps, and/or functions may also be added without departing from novel features disclosed herein. The apparatus, devices, and/or components illustrated in the figures may be configured to perform one or more of the methods, features, or steps described herein. The novel algorithms described herein may also be efficiently implemented in software and/or embedded in hardware.

It is to be understood that the specific order or hierarchy of steps in the methods disclosed is an illustration of exemplary processes. Based upon design preferences, it is understood that the specific order or hierarchy of steps in the methods may be rearranged. The accompanying method claims present elements of the various steps in a sample order, and are not meant to be limited to the specific order or hierarchy presented unless specifically recited therein.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but are to be accorded the full scope consistent with the language of the claims, wherein reference to an element in the singular is not intended to mean “one and only one” unless specifically so stated, but rather “one or more.” Unless specifically stated otherwise, the term “some” refers to one or more. A phrase referring to “at least one of” a list of items refers to any combination of those items, including single members. As an example, “at least one of: a, b, or c” is intended to cover: a; b; c; a and b; a and c; b and c; and a, b and c. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112, sixth paragraph, unless the element is expressly recited using the phrase “means for” or, in the case of a method claim, the element is recited using the phrase “step for.”

1. A level shifter circuit comprising:
a high voltage device;
a latch having a first side and a second side, wherein the latch is tied to a weak pull down to ground; and
a pair of current-mirror transistors; wherein a first current-mirror transistor of the pair includes a first current-mirror input coupled to the first side of the latch and a first current-mirror output coupled to the high voltage device; and wherein a second current-mirror transistor of the pair includes a second current-mirror input coupled to the second side of the latch and a second current-mirror output coupled to the high voltage device.

2. The level shifter circuit of claim 1, wherein the latch comprises a pair of diode-connected transistors, the pair of diode-connected transistors coupled to the weak pull down to ground through their gates.

3. The level shifter circuit of claim 1, wherein the high voltage device comprises a pair of inverters.

4. The level shifter circuit of claim 3, wherein the weak pull down to ground is implemented by a pair of complementary input transistors.

5. The level shifter circuit of claim 4, further comprising a high voltage source coupled to the pair of current-mirror transistors.

6. The level shifter circuit of claim 1, further comprising a pulse edge detector, wherein the pulse edge detector outputs a pulse waveform to a first input of the level shifter circuit and outputs a complementary pulse waveform to a second input of the level shifter circuit, the complementary pulse waveform being a complement of the pulse waveform.

7. The level shifter circuit of claim 6, wherein the pulse edge detector comprises at least two inverters, an XOR gate and a pair of AND gates, wherein the at least two inverters, the XOR gate and the pair of AND gates are coupled to each other in series.

8. The level shifter circuit of claim 7, wherein the pulse edge detector further comprises a delay element, the delay element coupled in series between the at least two inverters and the XOR gate.

9. The level shifter circuit of claim 8, wherein a square wave is inputted to one of the at least two inverters and to a first AND gate of the pair of AND gates; and wherein an inverted square wave is inputted to the second AND gate of the pair of AND gates, the inverted square wave being a complement of the square wave.

10. The level shifter circuit of claim 9, wherein the pulse waveform represents a plurality of leading edges of the square wave, and the complementary pulse waveform represents a plurality of falling edges of the square wave.

11. A level shifter circuit, comprising:
a ground and a high voltage source;
a first inverter having a first inverter input and a first inverter output;
a second inverter having a second inverter input and a second inverter output;
a pair of complementary input transistors having a first input transistor and a second input transistor, wherein the first input transistor includes a first input gate, a first input drain, and a first input source coupled to the ground, and the second input transistor includes a second input gate, a second input drain, and a second input source coupled to the ground;
a first diode-connected transistor having a first diode-connected source, a first diode-connected drain and a first diode-connected gate, wherein the first diode-connected drain and the first diode-connected gate are coupled to the first input drain;
a second diode-connected transistor having a second diode-connected source, a second diode-connected drain and a second diode-connected gate, wherein the second diode-connected drain and the second diode-connected gate are coupled to the second input drain; and
a pair of complementary current-mirror transistors having a first current-mirror transistor and a second current-mirror transistor; wherein the first current-mirror transistor includes a first current-mirror gate coupled to the first diode-connected gate, a first current-mirror drain coupled to the first inverter input and the second inverter output, and a first current-mirror source coupled to the high voltage source; and wherein the second current-mirror transistor includes a second current-mirror gate coupled to the second diode-connected gate, a second current-mirror drain coupled to the first inverter output and the second inverter input, and a second current-mirror source coupled to the high voltage source.

12. The level shifter circuit of claim 11, wherein the second inverter output is a first output of the level shifter circuit, and the first inverter output is a second output of the level shifter circuit.

13. The level shifter circuit of claim 12, wherein the first input gate is a first level shifter input, and the second input gate is a second level shifter input.

14. The level shifter circuit of claim 13, wherein a pulse waveform is inputted to the level shifter circuit through the first level shifter input, and a complementary pulse waveform is inputted through the second level shifter input, the complementary pulse waveform being a complement of the pulse waveform.

15. The level shifter circuit of claim 14, further comprising a pulse edge detector; wherein the pulse edge detector outputs the pulse waveform to the first level shifter input and the complementary pulse waveform to the second level shifter input.

16. The level shifter circuit of claim 15, wherein the pulse edge detector comprises at least two inverters, an XOR gate and a pair of AND gates, wherein the at least two inverters, the XOR gate and the pair of AND gates are coupled to each other in series.

17. The level shifter circuit of claim 11, further comprising:
a third inverter coupled in series to a fourth inverter;
an XOR gate coupled in series to the fourth inverter; and
a pair of AND gates coupled in parallel to each other, wherein the pair of AND gates is coupled in series to the XOR gate.

18. The level shifter circuit of claim 17, wherein a square wave is inputted to the third inverter and to a first AND gate of the pair of AND gates; and wherein an inverted square wave is inputted to the second AND gate of the pair of AND gates, the inverted square wave being a complement of the square wave.

19. The level shifter circuit of claim 18, wherein the first AND gate outputs a pulse waveform, the second AND gate outputs a complementary pulse waveform, the complementary pulse waveform being a complement of the pulse waveform.

20. The level shifter circuit of claim 19, wherein the pulse waveform is inputted to the level shifter circuit through the first input gate and the complementary pulse waveform is inputted through the second input gate.

21. A method for placement and routing one or more components on a level shifter circuit, the method comprising:
placing a high voltage device on the level shifter circuit;
placing a weak pull down to ground on the level shifter circuit;
coupling a latch to the weak pull down to ground, wherein the latch has a first side and a second side;
coupling a first input of a first current-mirror transistor to the first side of the latch, and coupling a first output of the first current-mirror transistor to the high voltage device; and
coupling a second input of a second current-mirror transistor to the second side of the latch, and coupling a second output of the second current-mirror transistor to the high voltage device.

22. The method of claim 21, further comprising coupling a high voltage source to the first current-mirror transistor and to the second current-mirror transistor.

23. The method of claim 22, wherein the coupling the latch to the weak pull down to ground comprises coupling a pair of diode-connected transistors to the weak pull down to ground through their gates.

24. The method of claim 22, wherein the high voltage device comprises a first inverter and a second inverter, and wherein a first inverter output is coupled to a second inverter input, and a second inverter output is coupled to a first inverter input.

25. The method of claim 24, further comprising:
coupling a third inverter in series to a fourth inverter;
coupling a delay element in series to the fourth inverter;
coupling an XOR gate in series to the delay element; and
coupling a pair of AND gates in series to the XOR gate, wherein the pair of AND gates are coupled in parallel to each other.

26. The method of claim 21, further comprising:
placing a first input transistor on the level shifter circuit and implementing the weak pull down to ground by coupling a first input source to a ground and by coupling a first input drain to a first diode-connected gate of the latch; and
placing a second input transistor on the level shifter circuit and implementing the weak pull down to ground by coupling a second input source to the ground and by coupling a second input drain to a second diode-connected gate of the latch.

27. A level shifter circuit comprising:
means for supplying a high voltage to the level shifter circuit;
means for grounding the level shifter circuit;
means for inputting at least one pulse waveform into the level shifter circuit, wherein the means for inputting the at least one pulse waveform is coupled to the means for grounding;
means for shunting an input current from the means for inputting;
means for generating a mirrored current associated with the means for inputting; and
means for latching an input voltage associated with the input current.

28. The level shifter circuit of claim 27, further comprising means for generating the at least one pulse waveform.

29. The level shifter circuit of claim 28, wherein the means for generating the at least one pulse waveform comprises a first inverter in series to a second inverter; a delay element in series to the second inverter; an XOR gate in series to the delay element; and a pair of AND gates in series to the XOR gate, wherein the pair of AND gates are coupled in parallel to each other.
